(19) United States
(12) Patent Application Publication
(10) Pub. No.: US 2026/0369520 A1
(43) Pub. Date: Nov. 19, 2026

(54) ION SOURCE FOR CONTROLLING DECOMPOSITION BUILDUP USING CLEANING GAS MIXTURE

(71) Applicant: Applied Materials, Inc., Santa Clara, CA (US)

(72) Inventors: Ori Noked, Brookline, MA (US); Graham Wright, Toronto (CA)

(21) Appl. No.: 19/660,388

(22) Filed: Apr. 28, 2026

Related U.S. Application Data
(60) Provisional application No. 63/806,515, filed on May 15, 2025.

(51) Int. Cl. H01J 37/30; H01J 37/304; H01J 37/317

(52) U.S. Cl. CPC H01J 37/3007; H01J 37/304; H01J 37/3171; H01J 2237/006; H01J 2237/022; H01J 2237/24542; H01J 2237/31705

(57) ABSTRACT

An ion source for generating an ion beam containing aluminum ions is disclosed. The ion source includes a first gas container to introduce an organoaluminium compound into the arc chamber of the ion source. A cleaning gas mixture, which includes several cleaning gasses, is also introduced to the arc chamber. The cleaning gas mixture reduces the buildup of decomposition material that occurs within the arc chamber. This buildup may occur at the gas bushing, the extraction aperture or near the repeller. In some embodiments, the cleaning gas mixture is introduced continuously. In other embodiments, the cleaning gas mixture is periodically introduced, based on hours of operation or the measured uniformity of the extracted ion beam. The cleaning gas mixture may be introduced from a second gas container, a plurality of gas containers or contained within the first gas container.

This application claims priority to U.S. Provisional Patent Application Serial No. 63/806,515, filed May 15, 2025, the disclosure of which is incorporated herein by reference in its entirety.

### FIELD

Embodiments of the present disclosure relate to an ion source and more particularly, an ion source for generating aluminum ions that controls decomposition buildup caused by the use of DMAC.

### BACKGROUND

Various types of ion sources may be used to create the ions that are used in semiconductor processing equipment. For example, an indirectly heated cathode (IHC) ion source operates by supplying a current to a filament disposed behind a cathode. The filament emits thermionic electrons, which are accelerated toward and heat the cathode, in turn causing the cathode to emit electrons into the arc chamber of the ion source. The cathode is disposed at one end of an arc chamber. A repeller may be disposed on the end of the arc chamber opposite the cathode. The cathode and repeller may be biased so as to repel the electrons, directing them back toward the center of the arc chamber. In some embodiments, a magnetic field is used to further confine the electrons within the arc chamber. A plurality of sides is used to connect the two ends of the arc chamber.

An extraction aperture is disposed along one of these sides, proximate the center of the arc chamber, through which the ions created in the arc chamber may be extracted.

In certain embodiments, it may be desirable to extract an ion beam that is made up of aluminum ions. Some gasses that are useful in creating an ion beam of aluminum ions are dimethylaluminum chloride (DMAC; (CH₃)₂AlCl) and trimethylaluminum (TMA; (CH₃)₃Al).

However, prolonged use of DMAC in an ion source chamber may result in the buildup of decomposition material, such as aluminum carbide and graphite. This buildup may form as hard coatings, whiskers, or flakes in the extraction aperture, on the gas bushings, or on the repeller. Whiskers in the extraction aperture lead to a nonuniform ion beam. Buildup around the gas bushing reduces or prevents the flow of gas into the ion source. Buildup on the repeller leads to shorting of this component.

Therefore, an ion source that is capable of operating using DMAC, TMA or other aluminum-containing gasses while preventing or controlling the buildup of decomposition material would be beneficial. Additionally, it would be advantageous if the ion source could operate continuously without needing a dedicated cleaning process.

### SUMMARY

An ion source for generating an ion beam containing aluminum ions is disclosed. The ion source includes a first gas container to introduce an organoaluminium compound into the arc chamber of the ion source. A cleaning gas mixture, which includes several cleaning gasses, is also introduced to the arc chamber. The cleaning gas mixture reduces the buildup of decomposition material that occurs within the arc chamber. This buildup may occur at the gas bushing, the extraction aperture or near the repeller. In some embodiments, the cleaning gas mixture is introduced continuously. In other embodiments, the cleaning gas mixture is periodically introduced, based on hours of operation or the measured uniformity of the extracted ion beam. The cleaning gas mixture may be introduced from a second gas container, a plurality of gas containers or contained within the first gas container.

According to one embodiment, an indirectly heated cathode ion source is disclosed. The indirectly heated cathode ion source comprises an arc chamber configured to generate a plasma; an indirectly heated cathode disposed in the arc chamber; a first gas that is an organoaluminium compound; a cleaning gas mixture, comprising two or more of an oxygen-containing gas, a fluorine-containing gas or a chlorine-containing gas; and a controller to control a flow of the first gas and the cleaning gas mixture into the arc chamber so as to extract an ion beam containing aluminum ions while simultaneously limiting a buildup of molecular byproducts created by decomposition of the first gas.

In some embodiments, the first gas is dimethylaluminum chloride (DMAC) or trimethylaluminum (TMA). In some embodiments, the fluorine-containing gas is molecular fluorine (F₂), BF₃, NF₃, PF₃, SiF₄, SF₆, CF₄, or C₂F₆. In some embodiments, the oxygen-containing gas is molecular oxygen (O₂), ozone (O₃), water vapor (H₂O), carbon dioxide (CO₂), nitrous oxide (N₂O), nitrogen dioxide (NO₂) or hydrogen peroxide (H₂O₂). In some embodiments, the chlorine-containing gas is molecular chlorine (Cl₂), HCl, CH₃Cl, CH₂Cl₂, CHCl₃, CCl₄, SiCl₄, or BCl₃.

In some embodiments, the controller introduces the cleaning gas mixture whenever the first gas is flowing in the arc chamber. In some embodiments, the controller introduces the cleaning gas mixture periodically while the first gas is being introduced into the arc chamber. In certain embodiments, the controller flows the cleaning gas mixture based on a number of hours of operation of the indirectly heated cathode ion source. In certain embodiments, a beam profiler is used to measure a uniformity of an ion beam extracted from the arc chamber and the controller flows the cleaning gas mixture based on the uniformity of the ion beam extracted from the arc chamber. In some embodiments, the controller introduces some cleaning gasses of the cleaning gas mixture whenever the first gas is being introduced into the arc chamber and introduces a remaining one or more cleaning gasses of the cleaning gas mixture periodically while the first gas is being introduced into the arc chamber.

In some embodiments, the cleaning gas mixture comprises the oxygen-containing gas, the fluorine-containing gas and the chlorine-containing gas. In some embodiments, the cleaning gas mixture comprises the oxygen-containing gas and the fluorine-containing gas and does not include the chlorine-containing gas. In some embodiments, the cleaning gas mixture comprises the oxygen-containing gas and the chlorine-containing gas and does not include the fluorine-containing gas. In some embodiments, the cleaning gas mixture comprises the fluorine-containing gas and the chlorine-containing gas and does not include the oxygen-containing gas.

In some embodiments, the first gas and the cleaning gas mixture are contained in a combined gas container. In some embodiments, the first gas and the cleaning gas mixture are contained in separate gas containers. In some embodiments, the first gas and each cleaning gas of the cleaning gas mixture are contained in separate gas containers. In some embodiments, the first gas and at least one cleaning gas of the cleaning gas mixture are contained in a combined gas container and a remaining cleaning gasses are contained within one or more cleaning gas containers.

In another embodiment, an ion implanter is disclosed. The ion implanter comprises any of the indirectly heated cathode ion sources described above, a mass analyzer and a workpiece holder.

### BRIEF DESCRIPTION OF THE FIGURES

For a better understanding of the present disclosure, reference is made to the accompanying drawings, which are incorporated herein by reference and in which:

FIGS. 1A-1B show two variations of an indirectly heated cathode (IHC) ion source in accordance with one embodiment;

FIG. 2 is an indirectly heated cathode (IHC) ion source in accordance with a second embodiment;

FIG. 3 is an indirectly heated cathode (IHC) ion source in accordance with a third embodiment;

FIG. 4 is an indirectly heated cathode (IHC) ion source in accordance with a fourth embodiment; and

FIG. 5 shows an ion implanter that uses the IHC ion sources of FIGS. 1A, 1B, 2-4.

### DETAILED DESCRIPTION

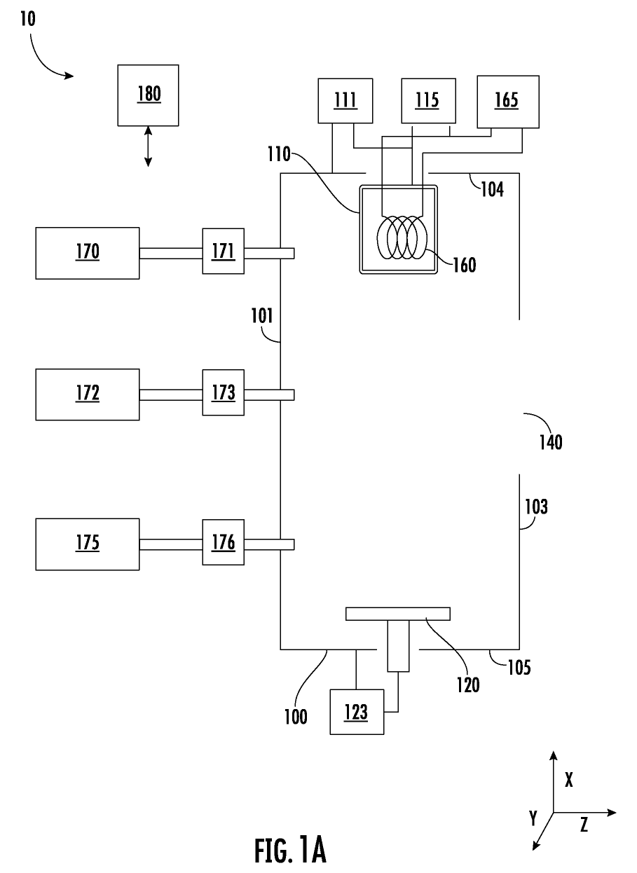

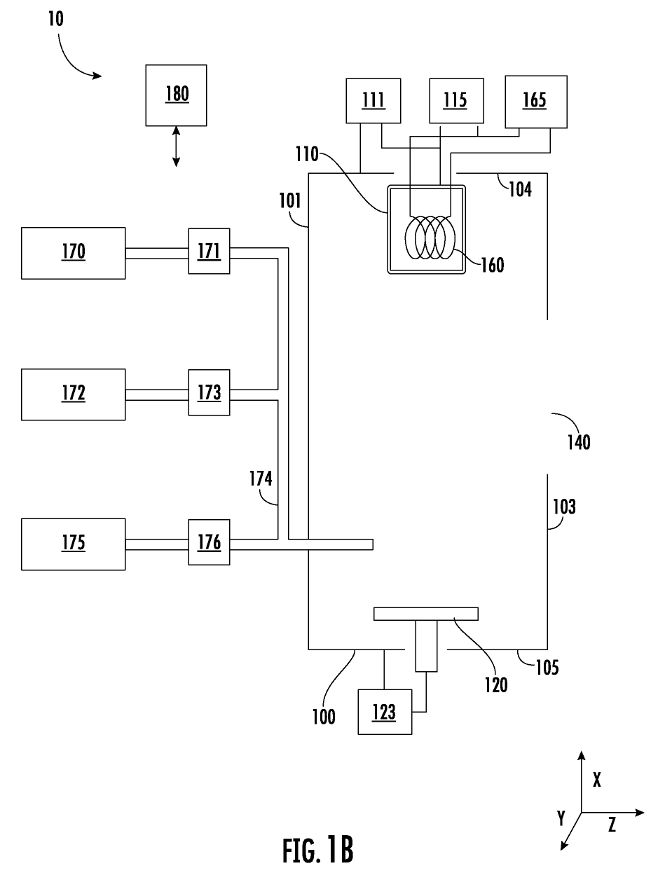

FIGS. 1A-1B show two variations of a first embodiment of an IHC ion source 10 that overcomes the issues associated with prolonged use of DMAC or TMA. The IHC ion source 10 includes an arc chamber 100, comprising two opposite ends, and walls 101 connecting to these ends. The walls 101 of the arc chamber 100 may be constructed of an electrically conductive material and may be in electrical communication with one another. In some embodiments, a liner may be disposed proximate one or more of the walls 101. A cathode 110 is disposed in the arc chamber 100 at a first end 104 of the arc chamber 100. A filament 160 is disposed behind the cathode 110. The filament 160 is in communication with a filament power supply 165. The filament power supply 165 is configured to pass a current through the filament 160, such that the filament 160 emits thermionic electrons. Cathode bias power supply 115 biases filament 160 negatively relative to the cathode 110, so these thermionic electrons are accelerated from the filament 160 toward the cathode 110 and heat the cathode 110 when they strike the back surface of cathode 110. The cathode bias power supply 115 may bias the filament 160 so that it has a voltage that is between, for example, 200V to 1500V more negative than the voltage of the cathode 110. The cathode 110 then emits thermionic electrons on its front surface into arc chamber 100.

Thus, the filament power supply 165 supplies a current to the filament 160. The cathode bias power supply 115 biases the filament 160 so that it is more negative than the cathode 110, so that electrons are attracted toward the cathode 110 from the filament 160. In certain embodiments, the cathode 110 may be biased relative to the arc chamber 100, such as by bias power supply 111. In other embodiments, the cathode 110 may be electrically connected to the arc chamber 100, so as to be at the same voltage as the walls 101 of the arc chamber 100. In these embodiments, bias power supply 111 may not be employed and the cathode 110 may be electrically connected to the walls 101 of the arc chamber 100. In certain embodiments, the arc chamber 100 is connected to electrical ground.

On the second end 105, which is opposite the first end 104, a repeller 120 may be disposed. The repeller 120 may be biased relative to the arc chamber 100 by means of a repeller bias power supply 123. In other embodiments, the repeller 120 may be electrically connected to the arc chamber 100, so as to be at the same voltage as the walls 101 of the arc chamber 100. In these embodiments, repeller bias power supply 123 may not be employed and the repeller 120 may be electrically connected to the walls 101 of the arc chamber 100. In still other embodiments, a repeller 120 is not employed or may be left electrically floating.

The cathode 110 and the repeller 120 are each made of an electrically conductive material, such as a metal or graphite.

In certain embodiments, a magnetic field is generated in the arc chamber 100. This magnetic field is intended to confine the electrons along one direction. The magnetic field typically runs parallel to the walls 101 from the first end 104 to the second end 105. For example, electrons may be confined in a column that is parallel to the direction from the cathode 110 to the repeller 120 (i.e., the X direction). Thus, electrons do not experience any electromagnetic force to move in the X direction. However, movement of the electrons in other directions may experience an electromagnetic force.

Disposed on one side of the arc chamber 100, referred to as the extraction plate 103, may be an extraction aperture 140. In FIGS. 1A-1B, 2, 3 and 4, the extraction aperture 140 is disposed on a side that is parallel to the X-Y plane (perpendicular to the page).

Further, the IHC ion source 10 may be in communication with one or more gas containers. The first gas container 170 may contain a first gas that is an organoaluminium compound, which is a compound in which an aluminum atom is bonded with a carbon atom, such as dimethylaluminum chloride (DMAC; (CH₃)₂AlCl) or trimethylaluminum (TMA; (CH₃)₃Al). A first valve 171 may be utilized to control the flow of the first gas from the first gas container 170 to the arc chamber 100.

A cleaning gas mixture is also introduced into the arc chamber 100. The cleaning gas mixture comprises two or more of the following species:
an oxygen-containing gas;
a fluorine-containing gas; or
a chlorine-containing gas.

The oxygen-containing gas may be molecular oxygen (O₂), ozone (O₃), water vapor (H₂O), carbon dioxide (CO₂), nitrous oxide (N₂O), nitrogen dioxide (NO₂), hydrogen peroxide (H₂O₂) or another oxygen-containing gas. The fluorine-containing gas may be molecular fluorine (F₂), BF₃, NF₃, PF₃, SiF_{4,} SF₆, CF₄, C₂F₆ or others. The chlorine-containing gas may be molecular chlorine (Cl₂), HCl, CH₃Cl, CH₂Cl₂, CHCl₃, CCl₄, SiCl₄, BCl₃ or another gas that is different from the first gas.

Thus, the cleaning gas mixture may contain the oxygen-containing gas and the fluorine-containing gas, the oxygen-containing gas and the chlorine-containing gas, the chlorine-containing gas and the fluorine-containing gas or all three gasses. In one specific embodiment, the cleaning gas mixture may be only the oxygen-containing gas. Additionally, one or more diluent gasses may also be included in the cleaning gas mixture.

In one embodiment, shown in FIGS. 1A-1B, the various gasses in the cleaning gas mixture are co-located in a second gas container 172. A second valve 173 may be utilized to control the flow of the cleaning gas mixture from the second gas container 172 to the arc chamber 100.

Further, a third gas container 175 may be present and may include various diluent gasses, such as hydrogen, argon or other gasses. A third valve 176 may be utilized to control the flow of the diluent gasses from the third gas container 175 to the arc chamber 100. The first valve 171, the second valve 173 and the third valve 176 may be mass flow controllers (MFC) such that the flow rate of each gas may be controlled. Gas bushings may be used to connect the outputs from the valves to the arc chamber 100.

A controller 180 may be in communication with one or more of the power supplies such that the voltage or current supplied by these power supplies may be modified. The controller 180 may also be in communication with the first valve 171, the second valve 173 and the third valve 176. The controller 180 may include a processing unit, such as a microcontroller, a personal computer, a special purpose controller, or another suitable processing unit. The controller 180 may also include a non-transitory storage element, such as a semiconductor memory, a magnetic memory, or another suitable memory. This non-transitory storage element may contain instructions and other data that allows the controller 180 to perform the functions described herein.

In the embodiment shown in FIGS. 1A-1B, the controller 180 is configured to allow the IHC ion source 10 to generate an ion beam that includes aluminum ions, while simultaneously minimizing buildup of decomposition material within the arc chamber 100.

In FIG. 1A, each valve 171, 173, 176 has an associated inlet that allows the flow of the gas directly to the arc chamber 100. In FIG. 1B, the outputs from the valves 171, 173, 176 connect to a common conduit 174 that enters the arc chamber 100. Further, note that other embodiments are also possible. For example, a subset of the valves, less than all of the valves, may share a common conduit while the remaining valves have dedicated conduits or another common conduit. Note that the use of one or more common conduits may be employed with any of the ion sources described herein.

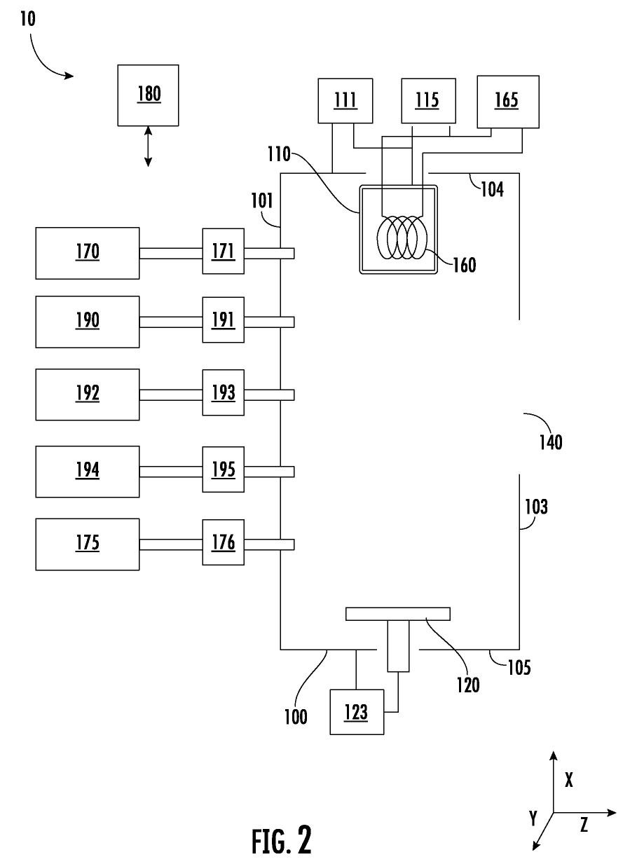

In another embodiment, shown in FIG. 2, the cleaning gasses are contained within separate gas containers. For example, there may be two or three cleaning gas containers that each contain one of the cleaning gasses that comprise the cleaning gas mixture. In this figure, there is a first cleaning gas container 190 containing the fluorine-containing gas, a second cleaning gas container 192 containing the oxygen-containing gas and a third cleaning gas container 194 containing the chlorine-containing gas. Each cleaning gas container may have a respective valve 191, 193, 195 to control the flow of each cleaning gas to the arc chamber 100. As noted above, two or more of these valves may be connected to a common conduit.

In some embodiments, only two of the three cleaning gas containers are used. In these embodiments, the respective valve for the other cleaning gas container may be omitted as well. Note that in these embodiments, the first gas container 170 and the third gas container 175 are as described above with respect to FIGS. 1A-1B.

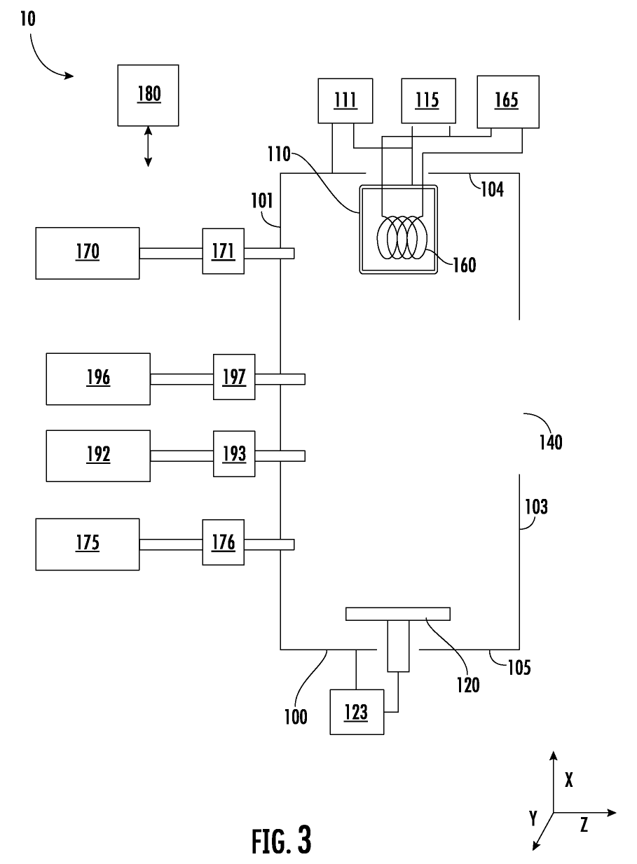

In yet another embodiment, shown in FIG. 3, two of the three cleaning gasses may be contained within a combined cleaning gas container 196 and the remaining cleaning gas may be in the second cleaning gas container 192. For example, the chlorine-containing gas and the fluorine-containing gas may be co-located in the combined cleaning gas container 196 and the oxygen-containing gas may be disposed in the second cleaning gas container 192. Of course, other combinations of these gasses are also possible. A valve 197 may be used to regulate the flow of the combined cleaning gasses to the arc chamber 100, while valve 193 is used to regulate the flow of the remaining cleaning gas to the arc chamber 100. Again, as noted above, two or more of these valves may be connected to a common conduit.

In each of the embodiments shown in FIGS. 1A, 1B, and 2-3, the flow of the cleaning gas mixture may be concurrent with the flow of the first gas, such that whenever first valve 171 is open, the cleaning gas mixture is also being introduced into the arc chamber 100. However, in other embodiments, the flow of the cleaning gas mixture may only flow when the first gas is flowing, but may not always be flowing while the first gas is flowing. Specifically, the controller 180 may periodically allow the flow of the cleaning gas mixture to facilitate a cleaning process while the first gas is being introduced and an ion beam is being extracted. In this embodiment, the controller 180 may enable the flow of the cleaning gas mixture after a predetermined number of hours of operation to remove the buildup of decomposition material. For example, the controller 180 may enable the flow of the cleaning gas mixture after 12-24 hours of operation. The cleaning gas mixture may flow into the ion source for a predetermined amount of time, such as between 15 minutes and 2 hours, to remove or reduce the buildup. While the cleaning gas mixture is flowing into the arc chamber 100, the first gas is also flowing, allowing aluminum ions to be generated and extracted from the arc chamber 100 during the cleaning process. After the buildup has been removed, the flow of cleaning gas mixture may be terminated. The timer may then be reset and this sequence may repeat a plurality of times. In another embodiment, the controller 180 may use feedback from a sensor to determine when the cleaning gas mixture is introduced into the arc chamber 100. For example, a beam profiler may be used to measure the uniformity of the extracted ion beam. If the uniformity is not within a predetermined threshold, such as within 1 %, the controller 180 may enable the flow of the cleaning gas mixture to remove deposits inside the arc chamber 100 of the ion source and enable a more uniform beam to be extracted. The flow of the cleaning gas mixture may be for a predetermined period of time, such as between 15 minutes and 2 hours, or may be related to the uniformity of the extracted ion beam.

Furthermore, in the embodiments shown in FIGS. 2-3, it is also possible for the controller 180 to flow some of the cleaning gasses whenever the first gas is flowing and periodically flow the remaining cleaning gasses. For example, in FIG. 2, the controller 180 may individually control valves 191, 193, 195 such that only some of the cleaning gasses are flowing whenever the first gas is flowing while the remaining cleaning gasses are only flowing some of the time that the first gas is flowing.

While FIGS. 1A, 1B, 2 and 3 show the first gas being contained in a separate gas container from the cleaning gasses, other embodiments are also possible.

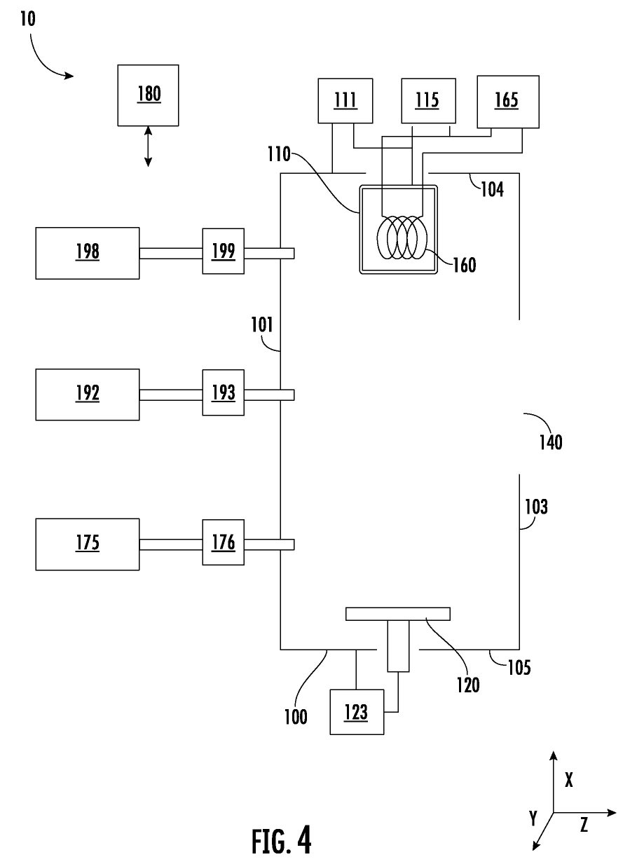

In yet another embodiment, shown in FIG. 4, some, but not all, of the cleaning gasses in the cleaning gas mixture are co-located with the first gas in a combined gas container 198, and one or more of the remaining cleaning gasses are located in one or more separate cleaning gas containers, such as second cleaning gas container 192. In this embodiment, valve 199 is used to regulate the flow of the combination of the first gas and some of the cleaning gasses. The controller 180 may flow all of the cleaning gasses whenever the first gas is flowing, or may flow only the cleaning gasses in the combined gas container 198 whenever the first gas is flowing. The remaining cleaning gasses may be flowed periodically, as explained above.

In some embodiments, all of the cleaning gasses in the cleaning gas mixture may be co-located with the first gas in a combined gas container 198. In this embodiment, the second cleaning gas container 192 and the valve 193 shown in FIG. 4 may be omitted, as the cleaning gas mixture is co-located in the combined gas container 198 with the first gas. In this way, whenever the valve 199 is opened, the first gas is flowing into the arc chamber 100, and the cleaning gas mixture is also being introduced to the arc chamber 100.

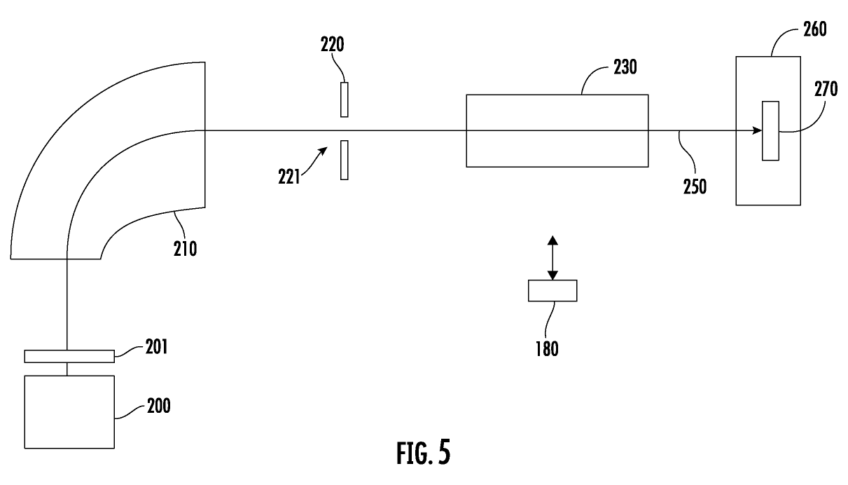

FIG. 5 shows an ion implanter that may use any of the ion sources shown in FIGS. 1A, 1B, 2-4. The ion source 200 is used to generate an ion beam 250. In some embodiments, the ion source 200 may output a ribbon ion beam. In other embodiments, the ion source 200 may output a spot beam. Disposed outside and proximate the extraction aperture of the ion source 200 is the extraction optics 201, which may comprise one or more electrodes.

Located downstream from the extraction optics 201 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the ion beam 250 that have a selected mass and charge will be directed through the resolving aperture 221. Other ions will strike the mass resolving device 220 or a wall of the mass analyzer 210 and will not travel any further in the system.

One or more components 230 may be located downstream from the mass resolving device 220 and upstream from the process chamber 260. These components may include a collimator in the case where the ion source 200 outputs a ribbon ion beam, or an electrostatic scanner in the case where the ion source 200 outputs a spot beam. Additionally, these components 230 may include focusing lenses and an acceleration and/or deceleration stage to independently control deflection, deceleration, and focus of the ion beam 250.

The ion beam 250 that exits the one or more components 230 enters the process chamber 260, where the workpiece holder 270 is located. A beam profiler may be disposed in or near the process chamber 260.

The controller 180 may be in communication with the valves, the mass analyzer 210, and one or more of the power supplies to control the implant process.

Note that while an IHC ion source is disclosed, the cleaning gas mixture may be used with any type of ion source, such as those that utilize capacitively coupled plasma, inductively coupled plasma, Bernas sources, and others. Thus, any ion source that includes an arc chamber that is configured to generate a plasma may be used. The plasma may be generated using a filament, an indirectly heated cathode, an antenna, or another component.

In operation, the first gas is introduced into the arc chamber 100 and the plasma is generated. The extraction optics 201 extract ions from the arc chamber 100. While the first gas is being introduced, the cleaning gas mixture is also introduced into the arc chamber 100, either continuously or periodically. The cleaning gas mixture serves to ensure that deposits do not form within the arc chamber 100 that affect the implant process. Thus, cleaning of the arc chamber 100 occurs concurrently with the implanting of the workpiece.

The embodiments described above in the present application may have many advantages. As described above, prolonged use of DMAC results in the buildup of molecular byproducts within the ion source. Oxygen, fluorine and chlorine each affect the byproducts differently. For example, adding fluoride-containing gas or oxygen-containing gas to the plasma helps with fractionation and removal of the carbohydrides but may produce non-volatile compounds such as AlF₃ and Al₂O₃ respectively. Adding a chlorine-containing gas may help break unwanted non-volatile compounds, such as AlF₃, Al₂O₃ and Al₄C₃. Thus, a cleaning gas mixture that comprises at least two of these cleaning gasses may be more effective in preventing the buildup of molecular byproducts.

Further, note that the cleaning gas mixture is introduced to the arc chamber 100 when the first gas is also flowing into the arc chamber 100. In this way, an ion beam that comprises aluminum ions may be extracted while the arc chamber 100 is being cleaned. Thus, there is no downtime associated with the cleaning of the arc chamber 100.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An indirectly heated cathode ion source, comprising:
an arc chamber configured to generate a plasma;
an indirectly heated cathode disposed in the arc chamber;
a first gas that is an organoaluminium compound;
a cleaning gas mixture, comprising two or more of an oxygen-containing gas, a fluorine-containing gas or a chlorine-containing gas; and
a controller to control a flow of the first gas and the cleaning gas mixture into the arc chamber so as to extract an ion beam containing aluminum ions while simultaneously limiting a buildup of molecular byproducts created by decomposition of the first gas.

2. The indirectly heated cathode ion source of claim 1, wherein the first gas is dimethylaluminum chloride (DMAC) or trimethylaluminum (TMA).

3. The indirectly heated cathode ion source of claim 1, wherein the fluorine-containing gas is molecular fluorine (F₂), BF₃ NF₃ PF₃ SiF₄ SF₆ CF₄ or C₂F₆.

4. The indirectly heated cathode ion source of claim 1, wherein the oxygen-containing gas is molecular oxygen (O₂), ozone (O₃), water vapor (H₂O), carbon dioxide (CO₂), nitrous oxide (N₂O), nitrogen dioxide (NO₂) or hydrogen peroxide (H₂O₂).

5. The indirectly heated cathode ion source of claim 1, wherein the chlorine-containing gas is molecular chlorine (Cl₂), HCl, CH₃Cl, CH₂Cl₂ CHCl₃ CCl₄ SiCl₄ or BCl₃.

6. The indirectly heated cathode ion source of claim 1, wherein the controller introduces the cleaning gas mixture whenever the first gas is flowing in the arc chamber.

7. The indirectly heated cathode ion source of claim 1, wherein the controller introduces the cleaning gas mixture periodically while the first gas is being introduced into the arc chamber.

8. The indirectly heated cathode ion source of claim 7, wherein the controller flows the cleaning gas mixture based on a number of hours of operation of the indirectly heated cathode ion source.

9. The indirectly heated cathode ion source of claim 7, further comprising a beam profiler to measure a uniformity of an ion beam extracted from the arc chamber and wherein the controller flows the cleaning gas mixture based on the uniformity of the ion beam extracted from the arc chamber.

10. The indirectly heated cathode ion source of claim 1, wherein the controller introduces some cleaning gasses of the cleaning gas mixture whenever the first gas is being introduced into the arc chamber and introduces a remaining one or more cleaning gasses of the cleaning gas mixture periodically while the first gas is being introduced into the arc chamber.

11. The indirectly heated cathode ion source of claim 1, wherein the cleaning gas mixture comprises the oxygen-containing gas, the fluorine-containing gas and the chlorine-containing gas.

12. The indirectly heated cathode ion source of claim 1, wherein the cleaning gas mixture comprises the oxygen-containing gas and the fluorine-containing gas and does not include the chlorine-containing gas.

13. The indirectly heated cathode ion source of claim 1, wherein the cleaning gas mixture comprises the oxygen-containing gas and the chlorine-containing gas and does not include the fluorine-containing gas.

14. The indirectly heated cathode ion source of claim 1, wherein the cleaning gas mixture comprises the fluorine-containing gas and the chlorine-containing gas and does not include the oxygen-containing gas.

15. The indirectly heated cathode ion source of claim 1, wherein the first gas and the cleaning gas mixture are contained in a combined gas container.

16. The indirectly heated cathode ion source of claim 1, wherein the first gas and the cleaning gas mixture are contained in separate gas containers.

17. The indirectly heated cathode ion source of claim 1, wherein the first gas and each cleaning gas of the cleaning gas mixture are contained in separate gas containers.

18. The indirectly heated cathode ion source of claim 1, wherein the first gas and at least one cleaning gas of the cleaning gas mixture are contained in a combined gas container and a remaining cleaning gasses are contained within one or more cleaning gas containers.

19. An ion implanter, comprising:
the indirectly heated cathode ion source of claim 1;
a mass analyzer; and
a workpiece holder.
